(19) United States
(12) Patent Application Publication
(10) Pub. No.: US 2024/0321713 A1
(43) Pub. Date: Sep. 26, 2024

(54) SEMICONDUCTOR PACKAGE

(71) Applicant: Samsung Electronics Co., Ltd., Suwon-si (KR)

(72) Inventors: Yoonyoung JEON, Suwon-si (KR); Dongheon KANG, Suwon-si (KR)

(73) Assignee: Samsung Electronics Co., Ltd., Suwon-si (KR)

(21) Appl. No.: 18/607,907

(22) Filed: Mar. 18, 2024

(30) Foreign Application Priority Data
Mar. 24, 2023 (KR) 10-2023-0038961
Apr. 21, 2023 (KR) 10-2023-0052987

(51) Int. Cl. H01L 23/498; H01L 23/31; H01L 23/00

(52) U.S. Cl. CPC H01L 23/49838; H01L 23/3128; H01L 23/49811; H01L 23/49822; H01L 24/16; H01L 2224/16225

(57) ABSTRACT

A semiconductor package may include a first redistribution structure, a semiconductor chip on the first redistribution structure, conductive posts spaced apart from the semiconductor chip and on the first redistribution structure, a molding layer on the first redistribution structure and surrounding the semiconductor chip and the conductive posts, and a second redistribution structure on the molding layer. The second redistribution structure may include a second redistribution pattern, a pad structure connected to the second redistribution pattern, and a second redistribution insulating layer. The second redistribution insulating layer may include a first insulating layer surrounding the second redistribution pattern and a second insulating layer surrounding at least a portion of the pad structure. The pad structure may include a second pad layer on a first pad layer. Surfaces of the first and second pad layers in contact with the second insulating layer may be concavo-convex.

### CROSS-REFERENCE TO RELATED APPLICATION

This application is based on and claims priority under 35 U.S.C. § 119 to Korean Patent Application Nos. 10-2023-0038961, filed on Mar. 24, 2023, and 10-2023-0052987, filed on Apr. 21, 2023, in the Korean Intellectual Property Office, the disclosures of each of which are incorporated by reference herein in their entirety.

### BACKGROUND

Inventive concepts relate to a semiconductor package. More specifically, inventive concepts relate to fan-out semiconductor packages.

According to the development of the electronics industry and the needs of users, miniaturization and weight reduction of electronic components mounted on electronic products may be required. Accordingly, the size of semiconductor packages mounted on electronic components is decreasing. At the same time, logic chips and memory chips included in semiconductor packages may be required to process high-capacity data. Accordingly, the number of input/output terminals of the semiconductor chip is greatly increased, and the interval between the input/output terminals is reduced, which may cause interference between the input/output terminals. Accordingly, a semiconductor package having connection terminals having connection reliability secured for a semiconductor chip is being devised. For example, to limit and/or prevent interference between connection terminals, a fan-out semiconductor package having an increased distance between connection terminals is being developed.

### SUMMARY

Inventive concepts provide a semiconductor package with improved structural reliability.

According to an embodiment of inventive concepts, a semiconductor package may include a first redistribution structure including a first redistribution pattern and a first redistribution insulating layer surrounding the first redistribution pattern; a semiconductor chip on the first redistribution structure; a plurality of conductive posts spaced apart from the semiconductor chip, the plurality of conductive posts on the first redistribution structure; a molding layer on the first redistribution structure, the molding layer surrounding the semiconductor chip and the plurality of conductive posts; and a second redistribution structure on the molding layer. The second redistribution structure may include a second redistribution pattern, a pad structure connected to the second redistribution pattern, and a second redistribution insulating layer. The second redistribution insulating layer may include a first insulating layer surrounding the second redistribution pattern and a second insulating layer surrounding at least a portion of the pad structure. The pad structure may include a first pad layer on the first insulating layer and a second pad layer on the first pad layer. Surfaces of the first pad layer in contact with the second insulating layer may be concavo-convex and surfaces of the second pad layer in contact with the second insulating layer may be concavo-convex.

According to an embodiment of inventive concepts, a semiconductor package may include a first redistribution structure including a first redistribution pattern and a first redistribution insulating layer surrounding the first redistribution pattern; a semiconductor chip on the first redistribution structure; a second redistribution structure on the semiconductor chip, the second redistribution structure including a second redistribution pattern, a pad structure connected to the second redistribution pattern, and a second redistribution insulating layer including a first insulating layer surrounding the second redistribution pattern and a second insulating layer surrounding at least a portion of the pad structure; an intermediate connection structure between the first redistribution structure and the second redistribution structure, the intermediate connection structure including an intermediate insulating layer and a plurality of through electrodes penetrating the intermediate insulating layer, the plurality of through electrodes electrically connecting the first redistribution structure to the second redistribution structure; and a molding layer surrounding at least a portion of the semiconductor chip and at least a portion of the intermediate connection structure. The pad structure may include a first pad layer on a first insulating layer and a second pad layer on the first pad layer. Surfaces of the first pad layer in contact with the second insulating layer may be concavo-convex and surfaces of the second pad layer in contact with the second insulating layer may be concavo-convex.

According to an embodiment of inventive concepts, a semiconductor package may include a first redistribution structure including a first redistribution pattern and a first redistribution insulating layer surrounding the first redistribution pattern; a semiconductor chip on the first redistribution structure; a plurality of conductive posts spaced apart from the semiconductor chip, the plurality of conductive posts on the first redistribution structure; a molding layer on the first redistribution structure, the molding layer surrounding the semiconductor chip and the plurality of conductive posts; a second redistribution structure on the molding layer, the second redistribution structure including a second redistribution pattern, a pad structure connected to the second redistribution pattern, and a second redistribution insulating layer, the second redistribution insulating layer including a first insulating layer surrounding the second redistribution pattern and a second insulating layer surrounding at least a portion of the pad structure; and an external connection terminal on a lower surface of the first redistribution structure. The pad structure may include a first pad layer on a first insulating layer, a second pad layer on the first pad layer, a first metal layer on the second pad layer, and a second metal layer on the first metal layer. Surfaces of the first pad layer in contact with the second insulating layer may be concavo-convex and surfaces of the second pad layer in contact with the second insulating layer may be concavo-convex. A horizontal length of the first pad layer in a first horizontal direction may be greater than a horizontal length of the second pad layer in the first horizontal direction. The first horizontal direction may be parallel to an upper surface of the first redistribution structure.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to embodiments;

FIG. 2 is an enlarged cross-sectional view of a portion EX1 of FIG. 1;

FIG. 3 is an enlarged cross-sectional view of a portion corresponding to EX1 in FIG. 1;

FIG. 4 is a cross-sectional view illustrating a semiconductor package according to embodiments;

FIG. 5 is an enlarged cross-sectional view of portion EX2 of FIG. 4;

FIG. 6 is a cross-sectional view illustrating a semiconductor package according to embodiments;

FIG. 7 is a cross-sectional view illustrating a semiconductor package according to embodiments;

FIG. 8 is an enlarged cross-sectional view of portion EX3 of FIG. 7; and

FIGS. 9, 10, 11A, 11B, 12A, 12B, 13A, 13B, 14A, 14B, 15A, 15B, 16, and 17 are diagrams for explaining a method of manufacturing a semiconductor package according to example embodiments.

### DETAILED DESCRIPTION

Hereinafter, embodiments of technical ideas of inventive concepts will be described in detail with reference to the accompanying drawings. The same reference numerals are used for the same components in the drawings, and duplicate descriptions thereof are omitted.

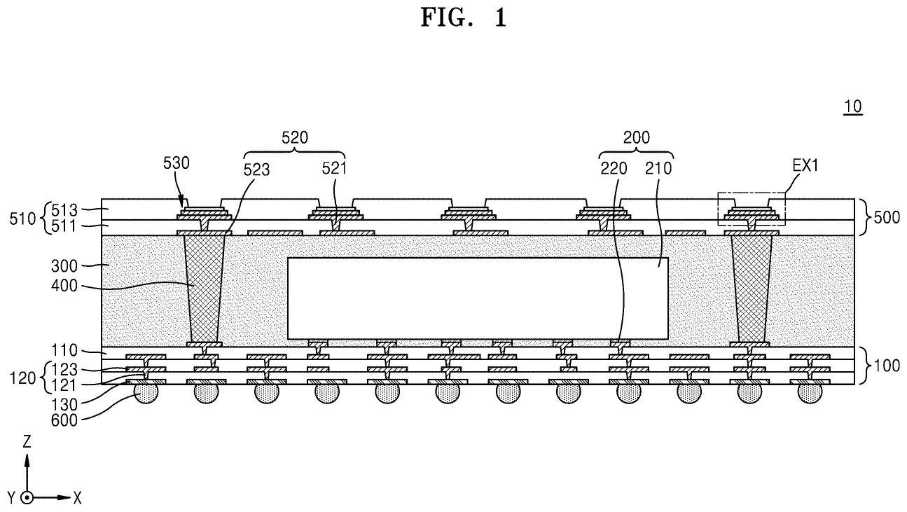

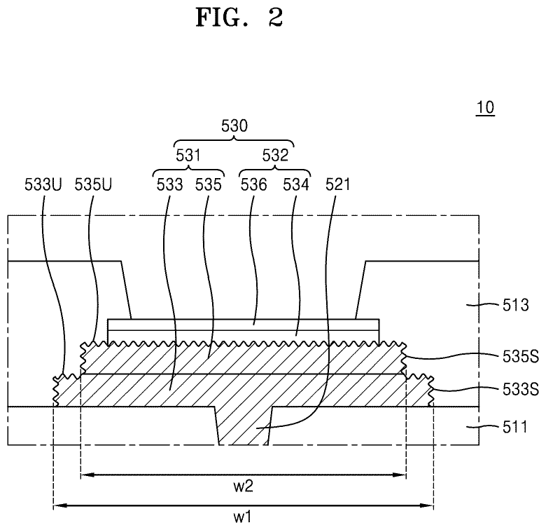

FIG. 1 is a cross-sectional view illustrating a semiconductor package 10 according to embodiments. FIG. 2 is an enlarged cross-sectional view of a portion EX1 of FIG. 1.

Referring to FIGS. 1 and 2, the semiconductor package 10 may include a first redistribution structure 100, a semiconductor chip 200, a molding layer 300, a plurality of conductive posts 400, and a second redistribution structure 500. In example embodiments, the semiconductor package 10 may be a lower semiconductor package constituting a package on package (POP) type semiconductor package.

The first redistribution structure 100 may include a plurality of first redistribution insulating layers 110, a plurality of first redistribution patterns 120, and a plurality of pads 130. Each of the plurality of first redistribution insulating layers 110 may include an insulating material. In example embodiments, the insulating material may include oxide or nitride. For example, the plurality of first redistribution insulating layers 110 may include silicon oxide or silicon nitride. In embodiments, the plurality of first redistribution insulating layers 110 may include a thermosetting resin such as epoxy resin, a thermoplastic resin such as polyimide, or a resin such as Ajinomoto Build-up Film (ABF), FR-4, and BT, in which reinforcing materials such as inorganic fillers are incorporated. The plurality of first redistribution insulating layers 110 may surround at least a portion of each of the plurality of first redistribution patterns 120 and at least a portion of each of the plurality of pads 130.

The plurality of first redistribution patterns 120 may include a plurality of first redistribution vias 121 and a plurality of first redistribution lines 123. Each of the plurality of first redistribution lines 123 may extend in a first horizontal direction (X direction) along the upper surface of the plurality of first redistribution insulating layers 110. Each of the plurality of first redistribution vias 121 may pass through the plurality of first redistribution insulating layers 110 and extend in the vertical direction (Z direction). The plurality of first redistribution vias 121 electrically connect first redistribution lines 123 to each other located at different vertical levels among the plurality of first redistribution lines 123, or may electrically connect the first redistribution line 123 positioned at the lowermost end among the plurality of first redistribution lines 123 to each of the plurality of pads 130 corresponding to the first redistribution line 123.

In example embodiments, each of the plurality of first redistribution vias 121 may have a tapered shape in which the length thereof in the first horizontal direction (length in the X direction) decreases as the distance from the semiconductor chip 200 increases in the vertical direction (Z direction).

In example embodiments, each of the plurality of first redistribution patterns 120 may include a metal such as Copper (Cu), Nickel (Ni), Gold (Au), Silver (Ag), Aluminum (Al), Tungsten (W), Titanium (Ti), Tantalum (Ta), Indium (In), Molybdenum (Mo), Manganese (Mn), Cobalt (Co), Tin (Sn), Magnesium (Mg), Rhenium (Rc), Beryllium (Be), Gallium (Ga), Ruthenium (Ru), and the like or an alloy thereof.

The plurality of pads 130 may be disposed on the lower surface of the first redistribution insulating layer 110 positioned lowermost among the plurality of first redistribution insulating layers 110. An external connection terminal 600 may be disposed on each of the plurality of pads 130. The semiconductor package 10 may be electrically connected to and mounted on a module board or system board of an electronic product through an external connection terminal 600. Each of the plurality of pads 130 may be an under bump metallurgy (UBM) connected to the external connection terminal 600.

In example embodiments, each of the plurality of pads 130 may have a same vertical length (Z-direction length). The bottom surface of each of the plurality of pads 130 on which the external connection terminal 600 is disposed may be a flat surface. For example, each of the plurality of pads 130 may include, for example, a metal, such as Copper (Cu), Aluminum (Al), Tungsten (W), Titanium (Ti), Tantalum (Ta), Indium (In), Molybdenum (Mo), Manganese (Mn), Cobalt (Co), Tin (Sn), Nickel (Ni), Magnesium (Mg), Rhenium (Re), Beryllium (Be), Gallium (Ga), Ruthenium (Ru), and the like, or an alloy thereof.

Although the first redistribution structure 100 is illustrated in FIG. 1 as including a first redistribution insulating layer 110 formed of three layers and first redistribution patterns 120 formed of three layers, inventive concepts are not limited to this. The number of first redistribution insulating layers and the number of layers of the first redistribution pattern may be variously modified according to the design of the first redistribution structure 100.

The semiconductor chip 200 may be disposed on the first redistribution structure 100. For example, the semiconductor chip 200 may be mounted on the first redistribution structure 100 in a flip chip method.

The semiconductor chip 200 may be a memory chip or a logic chip. The memory chip may be, for example, a volatile memory chip, such as a dynamic random access memory (DRAM) chip or a static random access memory (SRAM) chip, or may be a non-volatile memory chip, such as a phase-change random access memory (PRAM) chip, a magnetoresistive random access memory (MRAM) chip, a ferroelectric random access memory (FeRAM) chip, or a resistive random access memory (RRAM) chip. In some embodiments, the memory chip may be a high bandwidth memory (HBM) DRAM semiconductor chip. Also, the logic chip may be, for example, a microprocessor, an analog device, or a digital signal processor.

The semiconductor chip 200 may include a semiconductor substrate 210 and a plurality of chip pads 220 disposed on one surface of the semiconductor substrate 210. Each of the plurality of chip pads 220 may be connected to a portion of the redistribution line 123 positioned at the top among the plurality of redistribution lines 123. In example embodiments, the plurality of chip pads 220 may contact the redistribution line 123. In other embodiments, solder balls or solder bumps may be provided between the plurality of chip pads 220 and the redistribution line 123. In example embodiments, the plurality of chip pads 220 may include aluminum or an alloy including aluminum.

The semiconductor substrate 210 may include a group IV semiconductor, such as silicon (Si) or germanium (Ge), a group IV-IV compound semiconductor, such as silicon-germanium (SiGe) or silicon carbide (SiC), or a group III-V compound semiconductor, such as gallium arsenide (GaAs), indium arsenide (InAs), or indium phosphorus (InP). In addition, the semiconductor substrate 210 may include a conductive region, for example, a well doped with an impurity or a structure doped with an impurity.

The semiconductor substrate 210 may have an active surface and an inactive surface opposite to the active surface. For example, the active surface of the semiconductor substrate 210 may face the first redistribution structure 100. A semiconductor device including a plurality of individual devices of various types may be formed on the active surface of the semiconductor substrate 210. For example, the plurality of individual devices may include various microelectronic devices, for example, metal-oxide-semiconductor field effect transistors (MOSFETs) such as complementary metal-oxide-semiconductor (CMOS) transistors, system large scale integration (LSI), image sensors such as CMOS imaging sensors (CISs), micro-electro-mechanical systems (MEMS), active devices, passive devices, and the like.

The semiconductor chip 200 may receive at least one of a control signal, a power signal, and a ground signal for operation of the semiconductor chip 200 from the outside, receive a data signal to be stored in the semiconductor chip 200 from the outside, or provide data stored in the semiconductor chip 200 to the outside through the plurality of first redistribution patterns 120, the plurality of pads 130, and the external connection terminal 600 of the first redistribution structure 100.

The molding layer 300 may be disposed on the upper surface of the first redistribution structure 100. The molding layer 300 may surround at least a portion of the semiconductor chip 200 and at least a portion of the first redistribution line 123 positioned at the top among the plurality of first redistribution lines 123. The upper surface of the molding layer 300 may be positioned at a higher vertical level than the upper surface of the semiconductor chip 200 but are not limited thereto. The molding layer 300 may include, for example, an epoxy molding compound (EMC). However, inventive concepts are not limited thereto, and may include various materials such as epoxy-based materials, thermosetting materials, thermoplastic materials, and UV treated materials.

The plurality of conductive posts 400 may be disposed on the upper surface of the first redistribution structure 100 and spaced apart from side surfaces of the semiconductor chip 200 in the horizontal direction. For example, the semiconductor chip 200 may be disposed on the central portion of the first redistribution structure 100, and the plurality of conductive posts 400 may be spaced apart from the central portion thereof in a first horizontal direction (X direction) and a second horizontal direction (Y direction) and may be disposed on the edge portion of the first redistribution structure 100 surrounding the central portion thereof. Each of the plurality of conductive posts 400 may pass through the molding layer 300 and extend in the vertical direction (Z direction). Each of the plurality of conductive posts 400 may come into contact with a portion of the first redistribution line 123 positioned at the top among the plurality of first redistribution lines 123. The plurality of conductive posts 400 may be electrically connected to the semiconductor chip 200 through at least a portion of the plurality of first redistribution patterns 120. In addition, the plurality of conductive posts 400 may be electrically connected to the external connection terminal 600 through at least a portion of the plurality of first redistribution patterns 120 and the plurality of pads 130. The plurality of conductive posts 400 may include, for example, copper but are not limited thereto.

The second redistribution structure 500 may be disposed on the molding layer 300. The second redistribution structure 500 may be electrically connected to the first redistribution structure 100 through a plurality of conductive posts 400. The second redistribution structure 500 may include a plurality of second redistribution insulating layers 510, a plurality of second redistribution patterns 520, and a plurality of pad structures 530. The plurality of second redistribution insulating layers 510 may include a first insulating layer 511 and a second insulating layer 513. Here, the second insulating layer 513 refers to the uppermost insulating layer (e.g., the outermost insulating layer) among the plurality of second redistribution insulating layers 510, and the first insulating layer 511 may refer to the rest of the plurality of second redistribution insulating layers 510 except for the second insulating layer 513. The first insulating layer 511 may surround at least a portion of the plurality of second redistribution patterns 520, and the second insulating layer 513 may surround at least a portion of the plurality of pad structures 530. The plurality of second redistribution insulating layers 510 may include a material the same as or substantially the same as or similar to the plurality of first redistribution insulating layers 110 of the first redistribution structure 100.

The plurality of second redistribution patterns 520 may include a plurality of second redistribution vias 521 and a plurality of second redistribution lines 523. Each of the plurality of second redistribution lines 523 may extend in a first horizontal direction (X direction) along the upper surface of the plurality of second redistribution insulating layers 510. Each of the plurality of second redistribution vias 521 may pass through the first insulating layer 511 and extend in the vertical direction (Z direction). The plurality of second redistribution vias 521 may electrically connect the plurality of second redistribution lines 523 to the plurality of pad structures 530 corresponding thereto, respectively.

In embodiments, each of the plurality of second redistribution vias 521 may have a tapered shape in which as the distance from the semiconductor chip 200 in the vertical direction (Z direction) increases, the length thereof in the first horizontal direction (length in the X direction) increases.

The plurality of second redistribution patterns 520 may include materials the same as or substantially the same as or similar to those of the plurality of first redistribution patterns 120 of the first redistribution structure 100.

Although the second redistribution structure 500 is illustrated in FIG. 1 as including second redistribution insulating layers 510 formed of two layers (e.g., formed on two different vertical levels) and second redistribution patterns 520 formed of one layer, inventive concepts are not limited to this. The number of second redistribution insulating layers and the number of layers of the second redistribution pattern may be variously modified according to the design of the second redistribution structure 500.

Each of the plurality of pad structures 530 may be disposed on the lower surface of the second insulating layer 513. A portion of the upper surface of the plurality of pad structures 530 may be exposed without being covered by the second insulating layer 513. When the semiconductor package 10 is a lower semiconductor package constituting a package-on-package type semiconductor package, an upper semiconductor package (not shown) constituting a package-on-package type semiconductor package may be connected to the plurality of pad structures 530.

Each of the plurality of pad structures 530 may include a pad layer 531 and a metal layer 532. The pad layer 531 may include a first pad layer 533 and a second pad layer 535. The first pad layer 533 may be disposed on the lower surface of the second insulating layer 513. The first pad layer 533 may contact the second redistribution via 512 on the lower surface of the first layer 533. The first pad layer 533 may have side surfaces 533S and an upper surface 533U. Parts of the side surfaces 533S and the upper surface 533U of the first pad layer 533 may be surrounded by the second insulating layer 513, and the remaining portion of the upper surface 533U of the first pad layer 533 may contact the lower surface of the second pad layer 535. In example embodiments, among surfaces of the first pad layer 533, surfaces in contact with the second insulating layer 513 may include a concavo-convex structure. For example, among the side surfaces 533S and the upper surface 533U of the first pad layer 533, a portion that contacts the second insulating layer 513 may include a concave-convex structure, and the remaining portion (e.g., a portion of the upper surface of the first pad layer 533 in contact with the second pad layer 535) of the upper surface 533U of the first pad layer 533 that does not contact the second insulating layer 513 may not include a concavo-convex structure. The phrase “concavo-convex” also may be referred to as “concave-convex” and vice versa.

The second pad layer 535 may be disposed on the first pad layer 533. The second pad layer 535 may have side surfaces 535S and an upper surface 535U. Parts of the side surfaces 535S and the upper surface 535U of the second pad layer 535 may be surrounded by the second insulating layer 513, and the remaining portion of the upper surface 535U of the second pad layer 535 may contact the lower surface of the metal layer 532. In example embodiments, among surfaces of the second pad layer 535, surfaces in contact with the second insulating layer 513 may include a concavo-convex structure. For example, the side surfaces 535S and the upper surface 535U of the second pad layer 535 may include concavo-convex structures. That is, unlike the upper surface 533U of the first pad layer 533, the upper surface 535U of the second pad layer 535 may entirely include a concavo-convex structure.

In embodiments, the first pad layer 533 has a first horizontal width W1 in a first horizontal direction (X direction), the second pad layer 535 has a second horizontal width W2 in a first horizontal direction (X direction), and the first horizontal width W1 may be greater than the second horizontal width W2.

In example embodiments, the first pad layer 533 and the second pad layer 535 may include copper but are not limited thereto.

In example embodiments, the first pad layer 533 and the second pad layer 535 may be made of the same material. For example, the first pad layer 533 and the second pad layer 535 may be made of copper.

In example embodiments, the first pad layer 533 and the second pad layer 535 may have a rectangular cross-section. For example, the first pad layer 533 and the second pad layer 535 may have a rectangular cross-section on a plane perpendicular to the second horizontal direction (Y direction).

The metal layer 532 may include a first metal layer 534 and a second metal layer 536. The first metal layer 534 may be disposed on the second pad layer 535. At least a portion of side surfaces and the upper surface of the first metal layer 534 may be surrounded by the second insulating layer 513. The second metal layer 536 may be disposed on the first metal layer 534. At least a portion of the side surfaces and the upper surface of the second metal layer 534 may be surrounded by the second insulating layer 513, and the other part of the upper surface thereof may be exposed by the second insulating layer 513.

In example embodiments, the first metal layer 534 and the second metal layer 536 may include nickel, gold, or an alloy thereof.

In example embodiments, the first metal layer 534 and the second metal layer 536 may be made of different materials. For example, the first metal layer 534 may be made of nickel and the second metal layer 536 may be made of gold.

In example embodiments, the first metal layer 534 and the second metal layer 536 may have the same horizontal width. In other embodiments, the first metal layer 534 and the second metal layer 536 may have different horizontal widths. For example, the horizontal width of the first metal layer 534 may be greater than the horizontal width of the second metal layer 536.

In embodiments, the horizontal width of the first metal layer 534 in the first horizontal direction (X direction) and the horizontal width of the second metal layer 536 in the first horizontal direction (X direction) may be less than the second horizontal width W2 of the second pad layer 535.

The plurality of pad structures 530 of the semiconductor package 10 according to embodiments include a first pad layer 533 and a second pad layer 535, respectively, and a portion of the side surfaces 533S and the upper surface 533U of the first pad layer 533 contacting the second insulating layer 513 and a portion of the side surfaces 535S and the upper surface 535U of the second pad layer 535 contacting the second insulating layer 513 may include a concavo-convex structure. Accordingly, the contact area between the first pad layer 533 and the second insulating layer 513 and the contact area between the second pad layer 535 and the second insulating layer 513 increase, so that adhesion between each of the plurality of pad structures 530 and the second insulating layer 513 may be enhanced and structural reliability of the semiconductor package 10 may be improved.

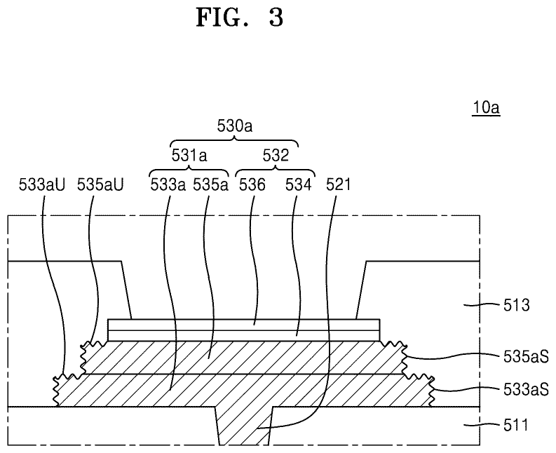

FIG. 3 is an enlarged cross-sectional view of a portion corresponding to EX1 in FIG. 1. Since each component of a semiconductor package 10a illustrated in FIG. 3 is similar to each component of the semiconductor package 10 described with reference to FIGS. 1 and 2, hereinafter, the differences therebetween are mainly described.

Referring to FIG. 3, the semiconductor package 10a may include a plurality of pad structures 530a disposed on the lower surface of the second insulating layer 513. Each of the plurality of pad structures 530a may include a pad layer 531a and a metal layer 532. The pad layer 531a may include a first pad layer 533a and a second pad layer 535a.

The first pad layer 533a may be disposed on the lower surface of the second insulating layer 513 and may contact the second redistribution via 521. The first pad layer 533a may have side surfaces 533aS and an upper surface 533aU. The first pad layer 533a included in the semiconductor package 10a may be substantially the same as or similar to the first pad layer 533 included in the semiconductor package 10 described with reference to FIGS. 1 and 2.

The second pad layer 535a may be disposed on the first pad layer 533a. The second pad layer 535a may have side surfaces 535aS and an upper surface 535aU. Parts of the side surfaces 535S and the upper surface 535U of the second pad layer 535 may be surrounded by the second insulating layer 513, and the remaining portion of the upper surface 535U of the second pad layer 535 may contact the lower surface of the metal layer 532. In embodiments, a portion of the side surfaces 535aS and the upper surface 535aU of the second pad layer 535a that is in contact with the second insulating layer 513 includes a concavo-convex structure, and the remaining portion (e.g., a portion of the upper surface of the second pad layer 535a in contact with the metal layer 532) of the upper surface 535aU of the second pad layer 535a that does not contact the second insulating layer 513 may not include a concavo-convex structure.

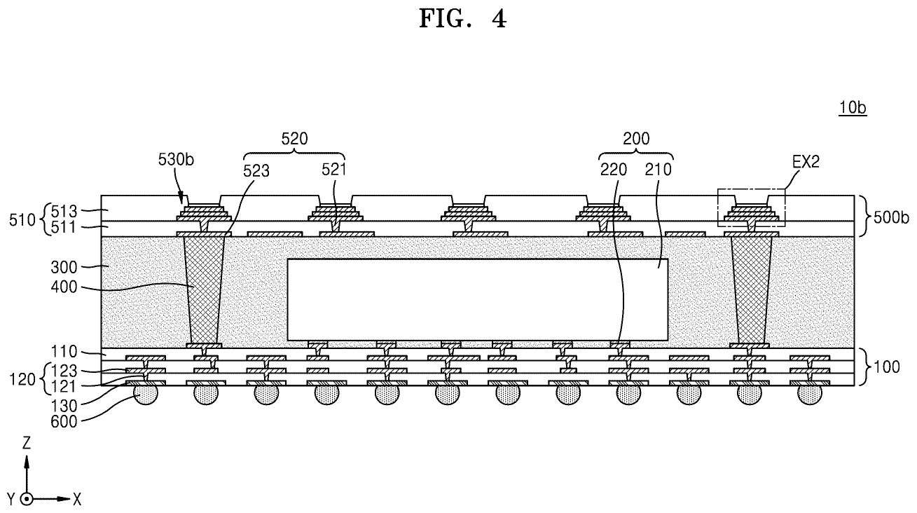

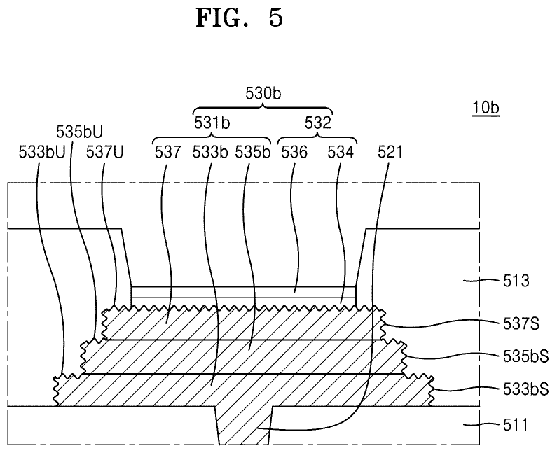

FIG. 4 is a cross-sectional view illustrating a semiconductor package 10b according to example embodiments. FIG. 5 is an enlarged cross-sectional view of portion EX2 of FIG. 4. Since each component of the semiconductor package 10b illustrated in FIGS. 4 and 5 is similar to each component of the semiconductor package 10 described with reference to FIGS. 1 and 2, hereinafter, the differences therebetween are mainly described.

Referring to FIGS. 4 and 5, the semiconductor package 10b may include a first redistribution structure 100, a semiconductor chip 200, a molding layer 300, a plurality of conductive posts 400, and a second redistribution structure 500b.

The second redistribution structure 500b may include a plurality of second redistribution insulating layers 510, a plurality of second redistribution patterns 520, and a plurality of pad structures 530b. Each of the plurality of pad structures 530b may include a pad layer 531b and a metal layer 532. The pad layer 531b may include a first pad layer 533b, a second pad layer 535b, and a third pad layer 537.

The first pad layer 533b may be disposed on the lower surface of the second insulating layer 513. The first pad layer 533b may have side surfaces 533bS and an upper surface 533bU. Parts of the side surfaces 533bS and the upper surface 533bU of the first pad layer 533b may be surrounded by the second insulating layer 513, and the remaining portion of the upper surface 533bU of the first pad layer 533b may contact the lower surface of the second pad layer 535b. In example embodiments, among surfaces of the first pad layer 533b, surfaces in contact with the second insulating layer 513 may include a concavo-convex structure. For example, a portion of the side surfaces 533bS and the upper surface 533bU of the first pad layer 533b that is in contact with the second insulating layer 513 may include a concave-convex structure, and the remaining portion (e.g., a portion of the upper surface of the first pad layer 533b that is in contact with the second pad layer 535b) of the upper surface 533bU of the first pad layer 533b that does not contact the second insulating layer 513 may not include a concavo-convex structure.

The second pad layer 535b may be disposed on the first pad layer 533b. The second pad layer 535b may have side surfaces 535bS and an upper surface 535bU. Parts of the side surfaces 535bS and the upper surface 535bU of the second pad layer 535b may be surrounded by the second insulating layer 513, and the remaining portion of the upper surface 535bU of the second pad layer 535b may contact the lower surface of the third pad layer 537. In example embodiments, among surfaces of the second pad layer 535b, surfaces in contact with the second insulating layer 513 may include a concavo-convex structure. For example, a portion of the side surfaces 535bS and the upper surface 535bU of the second pad layer 535b that is in contact with the second insulating layer 513 may include a concavo-convex structure, and the remaining portion (e.g., a portion of the upper surface of the second pad layer 535b in contact with the third pad layer 537) of the upper surface 535bU of the second pad layer 535b that does not contact the second insulating layer 513 may not include a concavo-convex structure.

The third pad layer 537 may be disposed on the second pad layer 535b. The third pad layer 537 may have side surfaces 537S and an upper surface 537U. Portions of the side surfaces 537S and the upper surface 537U of the third pad layer 537 may be surrounded by the second insulating layer 513, and the remaining portion of the upper surface 537U of the third pad layer 537 may contact the lower surface of the metal layer 532. In example embodiments, among surfaces of the third pad layer 537, surfaces in contact with the second insulating layer 513 may include a concavo-convex structure. For example, the side surfaces 537S and the upper surface 537U of the third pad layer 537 may include concavo-convex structures. However, technical ideas of inventive concepts are not limited thereto, and unlike those illustrated in FIGS. 4 and 5, a portion of the side surfaces 537S and the upper surface 537U of the third pad layer 537 that contacts the second insulating layer 513 may include a concave-convex structure, and the remaining portion (e.g., a portion of the upper surface of the third pad layer 537 in contact with the metal layer 532) of the upper surface 537U of the third pad layer 537 that is not in contact with the second insulating layer 513 may not include a concavo-convex structure.

In example embodiments, the first pad layer 533b may have a first horizontal width in a first horizontal direction (X direction), the second pad layer 535b has a second horizontal width that is less than the first horizontal width in a first horizontal direction (X direction), and the third pad layer 537 may have a third horizontal width that is less than the second horizontal width in a first horizontal direction (X direction).

In example embodiments, the first pad layer 533b, the second pad layer 535b, and the third pad layer 537 may include copper but are not limited thereto.

In example embodiments, the first pad layer 533b, the second pad layer 535b, and the third pad layer 537 may be made of the same material. For example, the first pad layer 533b, the second pad layer 535b, and the third pad layer 537 may be made of copper.

In FIGS. 4 and 5, the plurality of pad structures 530b are illustrated as including three pad layers, that is, the first, second, and third pad layers 533b, 535b, and 537, but are not limited thereto. For example, unlike those illustrated in FIGS. 4 and 5, the plurality of pad structures may include pad layers formed of four or more layers. In this case, side surfaces and the upper surface of the uppermost pad layer among the pad layers include a concavo-convex structure, side surfaces of each of the pad layers other than the uppermost pad layer among the pad layers and the portion of the upper surface in contact with the second insulating layer include a concavo-convex structure, and the remaining portion of the upper surface of each of the remaining pad layers not in contact with the second insulating layer may not include a concavo-convex structure.

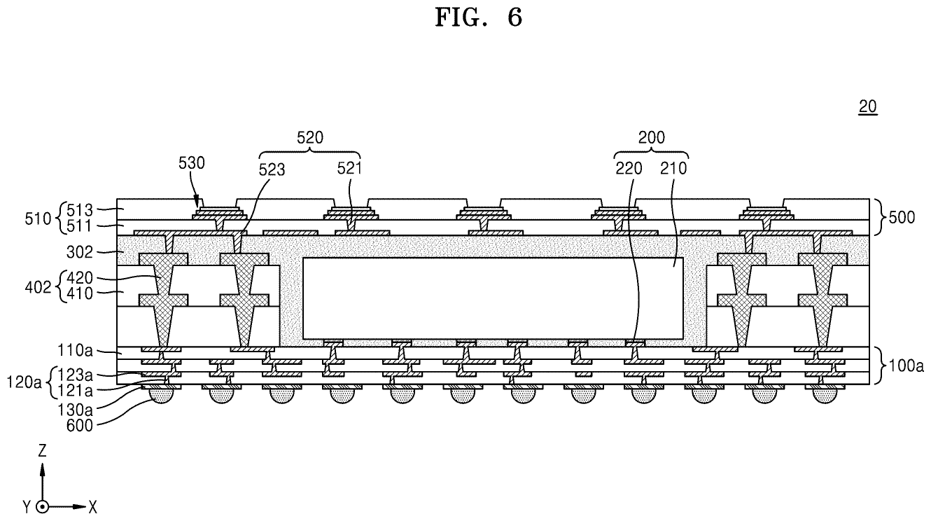

FIG. 6 is a cross-sectional view illustrating a semiconductor package 20 according to embodiments. Since each component of the semiconductor package 20 illustrated in FIG. 6 is similar to each component of the semiconductor package 10 described with reference to FIGS. 1 and 2, hereinafter, the differences therebetween are mainly described.

Referring to FIG. 6, the semiconductor package 20 may include a first redistribution structure 100a, a semiconductor chip 200, a molding layer 302, an intermediate connection structure 402, and a second redistribution structure 500.

The first redistribution structure 100a may include a plurality of first redistribution insulating layers 110a, a plurality of first redistribution patterns 120a, and a plurality of pads 130a. The plurality of first redistribution insulating layers 110a may include a material the same as or substantially the same as or similar to the plurality of first redistribution insulating layers 110 of the semiconductor package 10 illustrated in FIGS. 1 and 2. The plurality of first redistribution insulating layers 110a may surround at least a portion of each of the plurality of first redistribution patterns 120a.

The plurality of first redistribution patterns 120a may include a plurality of first redistribution vias 121a and a plurality of first redistribution lines 123a.

In embodiments, each of the plurality of first redistribution vias 121a may have a tapered shape in which as the distance from the semiconductor chip 200 in the vertical direction (Z direction) increases, the length thereof in the first horizontal direction (length in the X direction) increases.

The plurality of pads 130a may be disposed on the lower surface of the first redistribution insulating layer 110a positioned lowermost among the plurality of first redistribution insulating layers 110a. Side surfaces and lower surfaces of the plurality of pads 130a may be exposed without being surrounded by the first redistribution insulating layer 110a.

The intermediate connection structure 402 is disposed on the upper surface of the first redistribution structure 100a and may be horizontally spaced apart from side surfaces of the semiconductor chip 200. For example, the semiconductor chip 200 may be disposed on the central portion of the first redistribution structure 100a, and the intermediate connection structure 402 may be spaced apart from the central portion thereof in a first horizontal direction (X direction) and a second horizontal direction (Y direction) and may be disposed on the edge portion of the first redistribution structure 100a surrounding the central portion thereof.

The intermediate connection structure 402 may include intermediate insulating layers 410 and through silicon vias 420. The intermediate insulating layers 410 may horizontally surround the semiconductor chip 200. In example embodiments, the intermediate insulating layers 410 may be formed of at least one material selected from phenol resin, epoxy resin, and polyimide. For example, the intermediate insulating layers 410 may include at least one material selected from among Frame Retardant 4 (FR-4), Tetrafunctional epoxy, Polyphenylene ether, Epoxy/polyphenylene oxide, Bismaleimide triazine (BT), THERMOUNT® (a nonwoven aramid fiber reinforced substrate for printed wiring boards), Cyanate ester, Polyimide, and Liquid crystal polymer.

The through electrode 420 may pass through the intermediate insulating layers 410 and extend in the vertical direction (Z direction). The through electrode 420 may come into contact with a portion of the first redistribution line 123a located at the top among the plurality of first redistribution lines 123a. The through electrode 420 may be electrically connected to the semiconductor chip 200 through at least a portion of the plurality of first redistribution patterns 120a. Also, the through electrode 420 may be electrically connected to the external connection terminal 600 through at least a portion of the plurality of first redistribution patterns 120a and the plurality of pads 130a. The through electrode 420 may include, for example, copper but are not limited thereto.

In FIG. 6, the intermediate connection structure 402 is illustrated as including intermediate insulating layers 410 formed of two layers and through electrodes 420 formed of two layers but are not limited thereto. For example, intermediate insulating layers and through electrodes of the intermediate connection structure may be formed as a single layer.

The molding layer 302 may be disposed on the upper surface of the first redistribution structure 100a. The molding layer 302 may surround at least a portion of the semiconductor chip 200 and at least a portion of the intermediate connection structure 402. The molding layer 302 may include a material the same as or substantially the same as or similar to the molding layer 300 included in the semiconductor package 10 illustrated in FIGS. 1 and 2. The second redistribution structure 500 may be disposed on the molding layer 302.

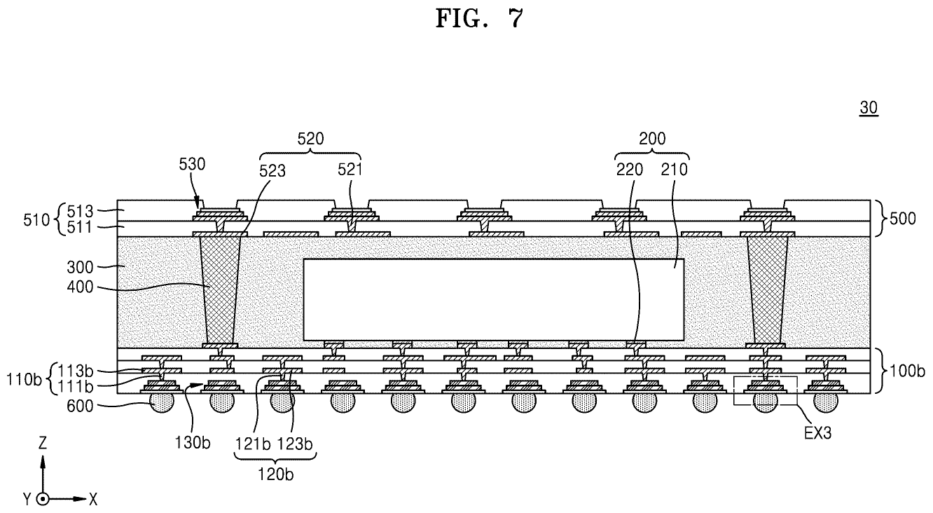

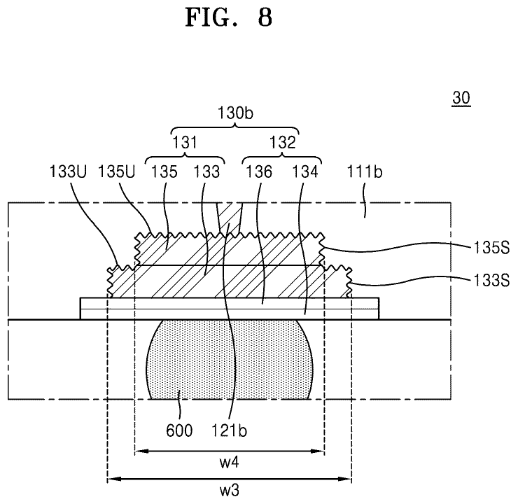

FIG. 7 is a cross-sectional view illustrating a semiconductor package 30 according to embodiments. FIG. 8 is an enlarged cross-sectional view of portion EX3 of FIG. 7. Since each component of the semiconductor package 30 illustrated in FIGS. 7 and 8 is similar to each component of the semiconductor package 10 described with reference to FIGS. 1 and 2, hereinafter, the differences therebetween are mainly described.

Referring to FIGS. 7 and 8, the semiconductor package 30 may include a first redistribution structure 100b, a semiconductor chip 200, a molding layer 300, a plurality of conductive posts 400, and a second redistribution structure 500.

The first redistribution structure 100b may include a plurality of first redistribution insulating layers 110b, a plurality of first redistribution patterns 120b, and a plurality of pad structures 130b. The plurality of first redistribution insulating layers 110b may include a first insulating layer 111b and a second insulating layer 113b. Here, the first insulating layer 111b refers to an insulating layer located at the bottom among the plurality of first redistribution insulating layers 110b (e.g., the outermost insulating layer), and the second insulating layer 113b may refer to the rest of the plurality of first redistribution insulating layers 110b except for the first insulating layer 111b. The first insulating layer 111b may surround at least a portion of the plurality of pad structures 130b, and the second insulating layer 113b may surround at least a portion of the plurality of first redistribution patterns 120b. The plurality of first redistribution insulating layers 110b may include a material the same as or substantially the same as or similar to the plurality of first redistribution insulating layers 110 of the semiconductor package 10 illustrated in FIGS. 1 and 2.

The plurality of first redistribution patterns 120b may include a plurality of first redistribution vias 121b and a plurality of first redistribution lines 123b. The plurality of first redistribution patterns 120b may have a structure substantially the same as or similar to the plurality of first redistribution patterns 120 of the semiconductor package 10 illustrated in FIGS. 1 and 2, and may include the same or substantially the same or similar materials.

A plurality of pad structures 130b may be disposed on the lower surface of the first insulating layer 111b. An external connection terminal 600 may be disposed on the bottom surface of each of the plurality of pads 130b. The semiconductor package 30 may be electrically connected to and mounted on a module board or system board of an electronic product through an external connection terminal 600.

Each of the plurality of pad structures 130b may include a pad layer 131 and a metal layer 132. The metal layer 132 may include a first metal layer 134 and a second metal layer 136. The first metal layer 134 may be disposed on the lower surface of the first insulating layer 111b. At least a portion of side surfaces and the upper surface of the first metal layer 134 may be surrounded by the first insulating layer 111b. The second metal layer 136 may be disposed on the first metal layer 134. At least a portion of side surfaces and the upper surface of the second metal layer 136 may be surrounded by the first insulating layer 111b, and the remaining portion of the upper surface may be surrounded by the first pad layer 133.

In example embodiments, the first metal layer 134 and the second metal layer 136 may include nickel, gold, or an alloy thereof.

In example embodiments, the first metal layer 134 and the second metal layer 136 may be made of different materials. For example, the first metal layer 134 may be made of gold and the second metal layer 136 may be made of nickel.

In example embodiments, the first metal layer 134 and the second metal layer 136 may have the same horizontal width. In other embodiments, the first metal layer 134 and the second metal layer 136 may have different horizontal widths in the first horizontal direction (X direction). For example, the horizontal width of the first metal layer 134 may be greater than the horizontal width of the second metal layer 136.

The pad layer 131 may include a first pad layer 133 and a second pad layer 135. The first pad layer 133 may be disposed on the lower surface of the first insulating layer 111b. The lower surface of the first pad layer 133 may contact the metal layer 132. The first pad layer 133 may have side surfaces 133S and an upper surface 133U. Portions of the side surfaces 133S and the upper surface 133U of the first pad layer 133 may be surrounded by the first insulating layer 111b, and the remaining portion of the upper surface 533U of the first pad layer 133 may contact the lower surface of the second pad layer 535. In example embodiments, among the surfaces of the first pad layer 133, surfaces in contact with the first insulating layer 111b may have a concavo-convex structure. For example, among the side surfaces 133S and the upper surface 133U of the first pad layer 133, a portion in contact with the first insulating layer 111b may include a concavo-convex structure, and the remaining portion (e.g., a portion of the upper surface of the first pad layer 133 in contact with the second pad layer 135) of the upper surface 133U of the first pad layer 133 that does not contact the first insulating layer 111b may not include a concavo-convex structure.

The second pad layer 135 may be disposed on the first pad layer 133. The second pad layer 135 may have side surfaces 135S and an upper surface 135U. Portions of the side surfaces 135S and the upper surface 135U of the second pad layer 135 may be surrounded by the first insulating layer 111b, and the remaining portion of the upper surface 135U of the second pad layer 135 may contact the lower surface of the first redistribution via 121b. In example embodiments, among the surfaces of the second pad layer 135, surfaces in contact with the first insulating layer 111b may have a concavo-convex structure. For example, the side surfaces 135S and the upper surface 135U of the second pad layer 135 may include concavo-convex structures. That is, unlike the upper surface 133U of the first pad layer 133, the upper surface 135U of the second pad layer 135 may entirely include a concavo-convex structure.

In example embodiments, the first pad layer 133 has a third horizontal width W3 in the first horizontal direction (X direction), and the second pad layer 135 has a fourth horizontal width W4 in the first horizontal direction (X direction), and the third horizontal width W3 may be greater than the fourth horizontal width W4.

The first pad layer 133 and the second pad layer 135 are the same or substantially similar to the first pad layer 531 and the second pad layer 535 of the semiconductor package 10 illustrated in FIGS. 1 and 2, respectively, and may include the same or similar materials.

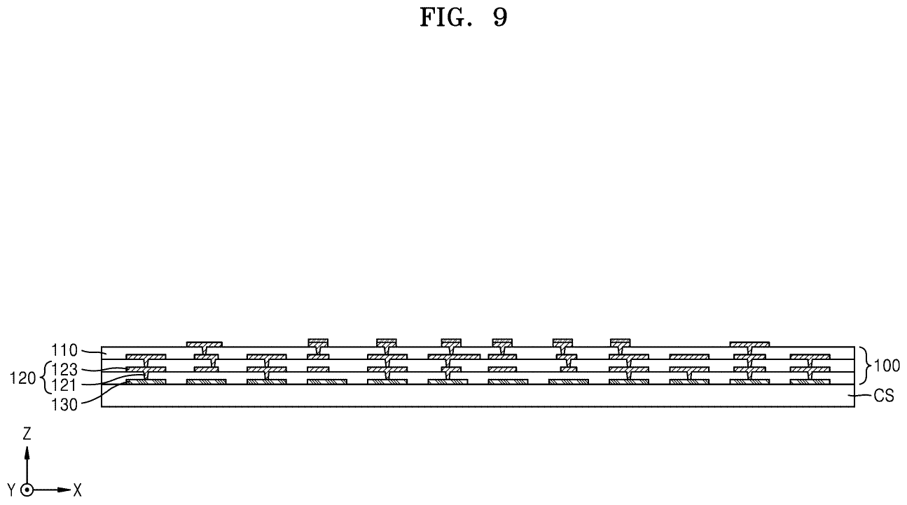

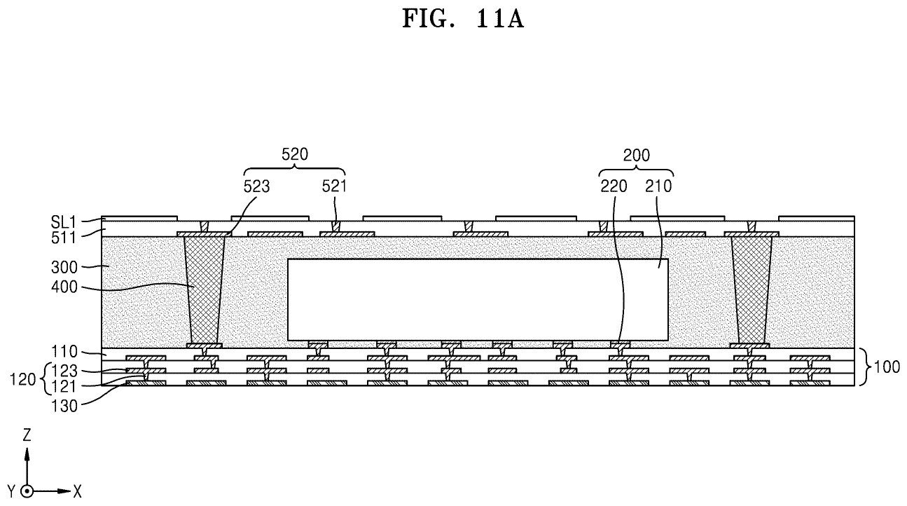

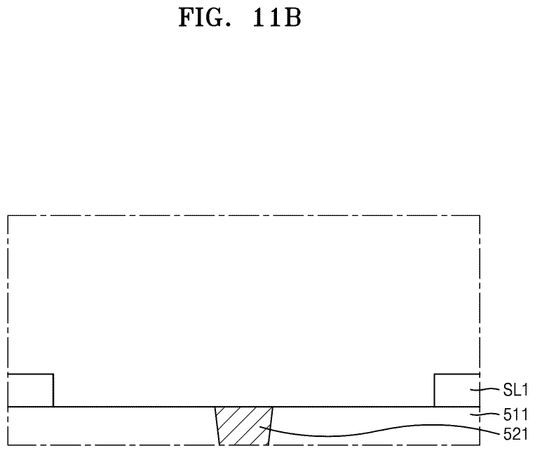

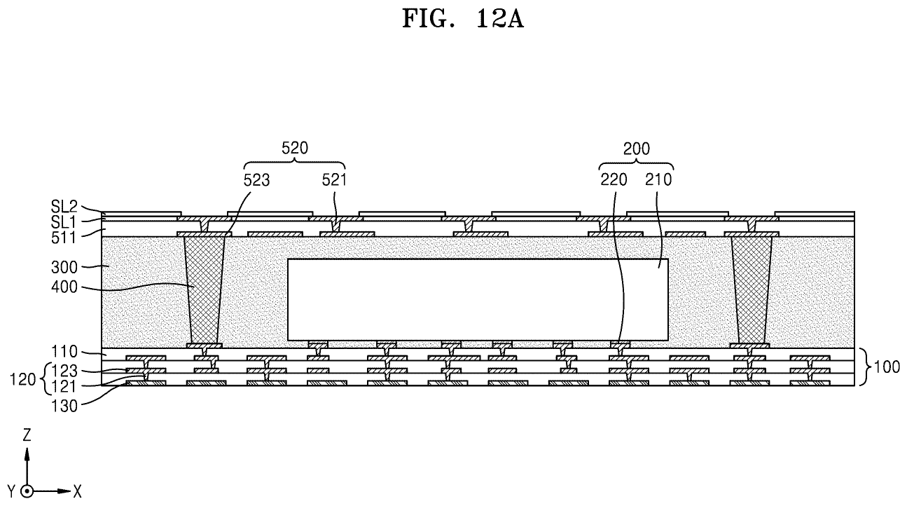

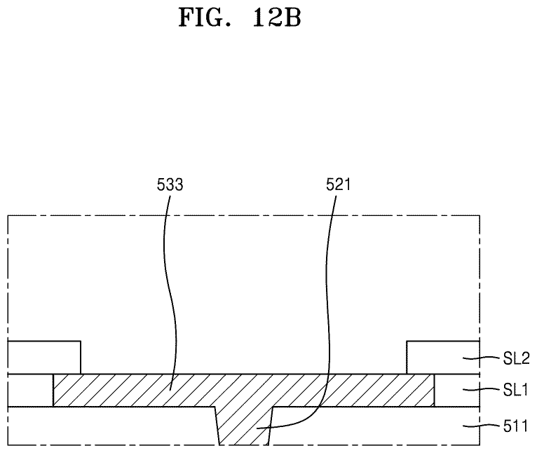

FIGS. 9, 10, 11A, 11B, 12A, 12B, 13A, 13B, 14A, 14B, 15A, 15B, 16, and 17 are diagrams for explaining a method of manufacturing the semiconductor package 10, according to embodiments. Specifically, FIGS. 9, 10, 11A, 12A, 13A, 14A, 15A, 16, and 17 are cross-sectional views for explaining a method of manufacturing the semiconductor package 10, according to embodiments, and FIGS. 12B, 13B, 14B, and 15B are enlarged cross-sectional views of portions corresponding to EX1 in FIG. 1 in FIGS. 11A, 12A, 13A, 14A, and 15A, respectively.

Referring to FIG. 9, a first redistribution structure 100 may be formed on a provided support substrate CS. The support substrate CS may be, for example, an insulating substrate made of glass or polymer or a conductive substrate made of metal. After forming an insulating layer on the support substrate CS and patterning the insulating layer to form openings penetrating the insulating layer, the first redistribution structure 100 may be formed by repeatedly filling the opening with a conductive material.

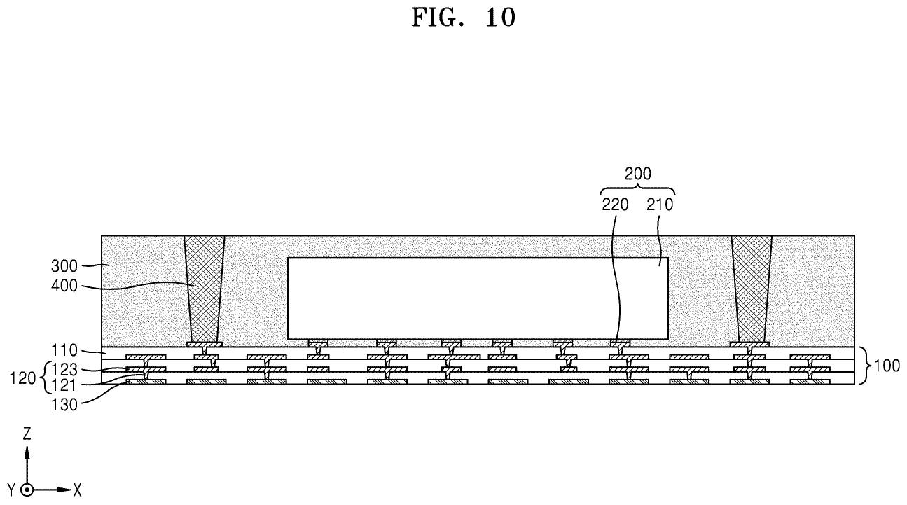

Referring to FIG. 10, in the result of FIG. 9, the semiconductor chip 200 is mounted on the central portion of the first redistribution structure 100, and a plurality of conductive posts 400 may be formed on the edge portion of the first redistribution structure 100 horizontally surrounding the central portion thereof. The semiconductor chip 200 may be mounted in a flip chip method, for example. A plurality of conductive posts 400 may be formed on the first redistribution structure 100 to overlap the portion of the first redistribution line 123 located at the top among the first redistribution lines 123 of the first redistribution structure 100 in the vertical direction (Z direction). For example, after forming a sacrificial layer on the first redistribution structure 100 and forming a through hole through the sacrificial layer to expose a portion of the first redistribution line 123 located at the top among the first redistribution lines 123, the plurality of conductive posts 400 may be formed by filling the through holes with a conductive material. Next, a molding layer 300 may be formed on the upper surface of the first redistribution structure 100. The molding layer 300 may surround the semiconductor chip 200 and the plurality of conductive posts 400.

In embodiments, unlike described with reference to FIGS. 9 and 10, after mounting the semiconductor chip 200 on the first redistribution structure 100, forming a molding layer 300 covering the semiconductor chip 200 on the first redistribution structure 100, and forming a through hole exposing a portion of the uppermost first redistribution line 123 among the first redistribution lines 123 in the molding layer 300, a plurality of conductive posts 400 may be formed by filling the through hole with a conductive material.

Referring to FIGS. 11A and 11B, in the result of FIG. 10, a first insulating layer 511 and a second redistribution pattern 520 may be formed on the molding layer 300. The first insulating layer 511 and the second redistribution pattern 520 may be formed in a manner similar to that of the first redistribution structure 100. Next, a first sacrificial layer SL1 is formed on the first insulating layer 511 and the first sacrificial layer SL1 is patterned, so that a first opening (not shown) exposing the second redistribution via 521 may be formed.

Referring to FIGS. 12A and 12B, in the results of FIGS. 11A and 11B, a first pad layer 533 may be formed by filling the first opening with a conductive material. Next, a second sacrificial layer SL2 covering the first sacrificial layer SL1 and the first pad layer 533 is formed, and a second opening (not shown) exposing the first pad layer 533 may be formed by patterning the second sacrificial layer SL2. In this case, the horizontal width of the second opening in the first horizontal direction (X direction) may be less than the horizontal width of the first pad layer 533 in the first horizontal direction (X direction).

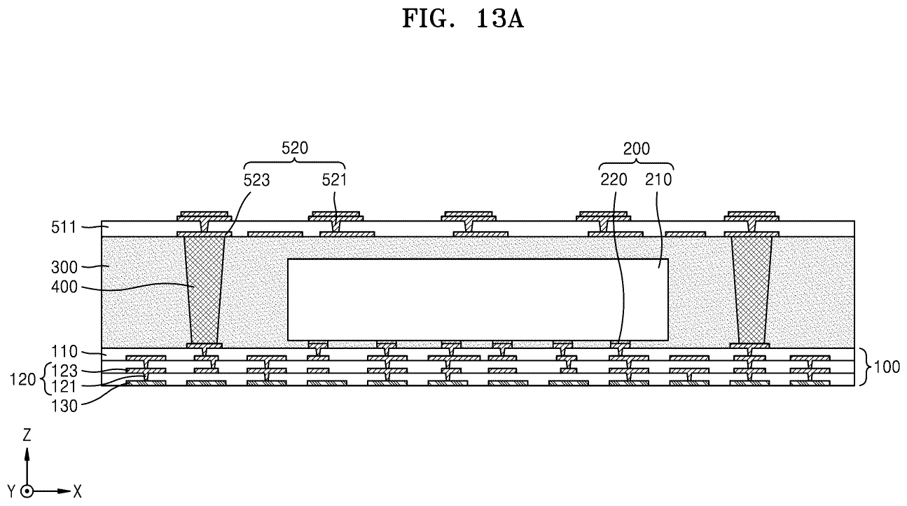

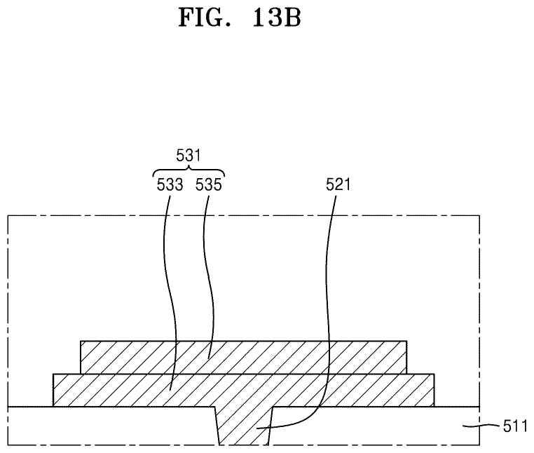

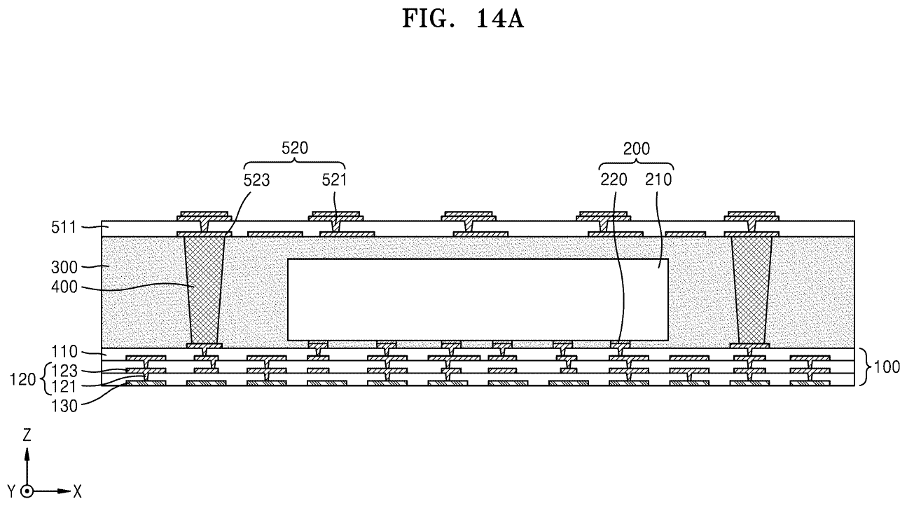

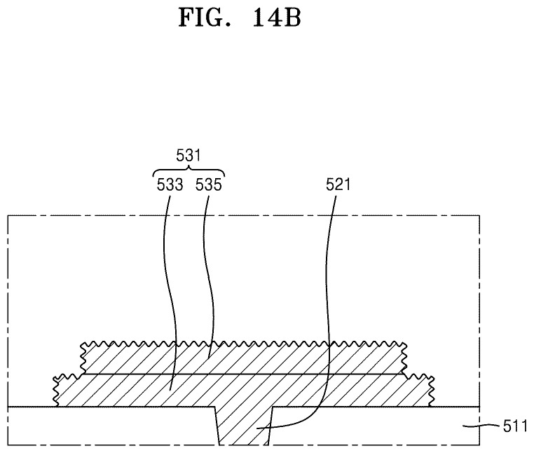

Referring to FIGS. 13A and 13B, in the results of FIGS. 12A and 12B, a second pad layer 535 may be formed by filling the second opening with a conductive material. In example embodiments, the material forming the first pad layer 533 and the material forming the second pad layer 535 may be the same. Next, the upper surface of the first insulating layer 511 may be exposed by removing the first sacrificial layer SL1 and the second sacrificial layer SL2. However, technical ideas of inventive concepts are not limited thereto, and a plurality of pad layers disposed on the second pad layer 535 may be further formed by repeating the pad layer forming process described with reference to FIGS. 12A, 12B, 13A, and 13B. Thereafter, by performing the roughness process described below with reference to FIGS. 14A and 14B, the result is disposed on the second pad layer 535 like the semiconductor package 10b illustrated in FIGS. 4 and 5, and a plurality of pad layers having a concave-convex structure on a surface contacting the second insulating layer 513 (see FIG. 4) may be formed.

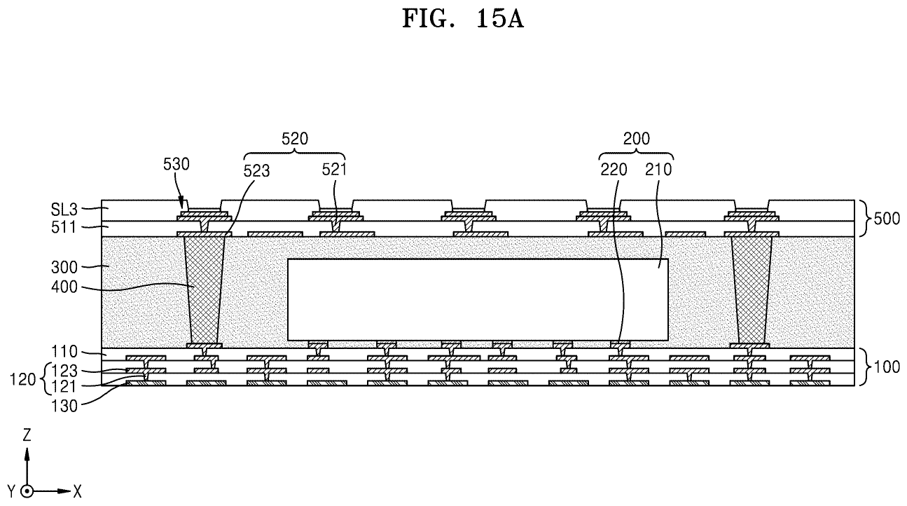

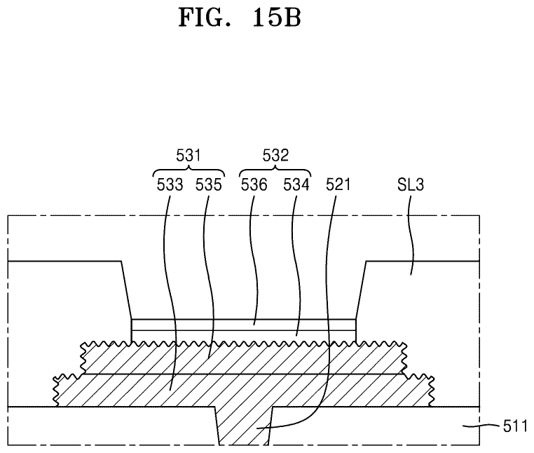

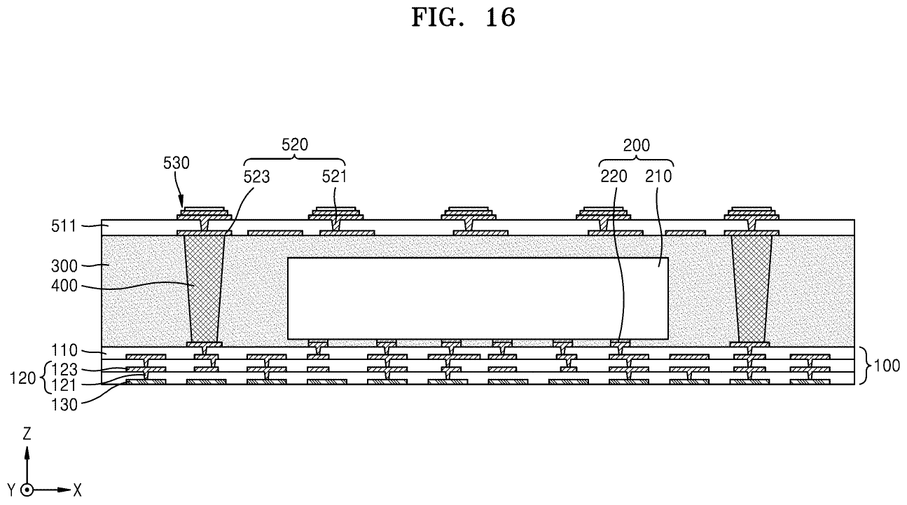

Referring to FIGS. 14A and 14B, a roughness treatment such as CZ treatment may be performed on the first pad layer 533 and the second pad layer 535 in the results of FIGS. 13A and 13B. By the roughening treatment, a concavo-convex structure may be formed on the side surfaces of the first pad layer 533, the exposed portion of the upper surface of the first pad layer 533, the side surfaces of the second pad layer 535, and the upper surface of the second pad layer 535. However, technical ideas of inventive concepts are not limited thereto, and the roughness treatment may be performed after removing the third sacrificial layer SL3 (see FIG. 15A), as described below with reference to FIG. 16, for example. In this case, since the metal layer 532 is formed on the upper surface of the second pad layer 535, as in the semiconductor package 10a illustrated in FIG. 2, a portion of the upper surface of the second pad layer 535 in contact with the first metal layer 534 may not include a concavo-convex structure.

Referring to FIGS. 15A and 15B, in the results of FIGS. 14A and 14B, a third sacrificial layer SL3 covering the first insulating layer 511, the first pad layer 533, and the second pad layer 535 may be formed, and a third opening (not shown) exposing the upper surface of the second pad layer 535 may be formed by patterning the third sacrificial layer SL3. Next, a first metal layer 534 and a second metal layer 536 may be sequentially formed on the second pad layer 535 exposed through the third opening. The first metal layer 534 may be formed on the upper surface of the second pad layer 535 having a concavo-convex structure. Accordingly, the lower surface of the first metal layer 534 may correspond to the concave-convex structure included in the upper surface of the second pad layer 535. The first metal layer 534 and the second metal layer 536 may be formed through, for example, a deposition process. By forming the metal layer 532 including the first metal layer 534 and the second metal layer 536, the metal layer 532 and the pad layer 531 may configure the pad structure 530.

Referring to FIG. 16, in the results of FIGS. 15A and 15B, the third sacrificial layer SL3 (see FIG. 15A) may be removed. As the third sacrificial layer SL3 is removed, the first insulating layer 511 and the pad structure 530 may be exposed.

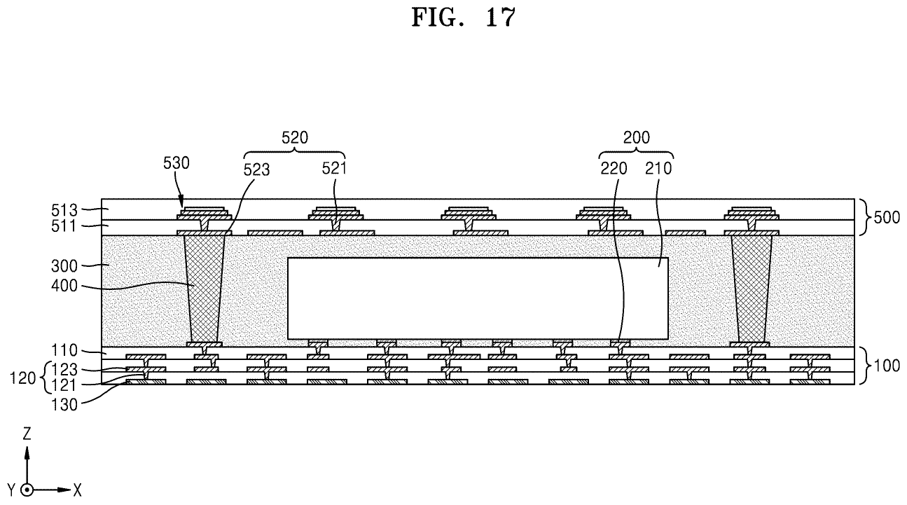

Referring to FIG. 17, in the result of FIG. 16, a second insulating layer 513 covering the upper surface of the first insulating layer 511 and the pad structure 530 may be formed. Next, the semiconductor package 10 illustrated in FIGS. 1 and 2 may be manufactured by forming an opening exposing the upper surface of the second metal layer 536 of the pad structure 530.

While inventive concepts have been particularly shown and described with reference to embodiments thereof, it will be understood that various changes in form and details may be made therein without departing from the spirit and scope of the following claims.

What is claimed is:

1. A semiconductor package comprising:
a first redistribution structure including a first redistribution pattern and a first redistribution insulating layer surrounding the first redistribution pattern;
a semiconductor chip on the first redistribution structure;
a plurality of conductive posts spaced apart from the semiconductor chip, the plurality of conductive posts on the first redistribution structure;
a molding layer on the first redistribution structure, the molding layer surrounding the semiconductor chip and the plurality of conductive posts; and
a second redistribution structure on the molding layer,
the second redistribution structure including a second redistribution pattern, a pad structure connected to the second redistribution pattern, and a second redistribution insulating layer, and
the second redistribution insulating layer including a first insulating layer surrounding the second redistribution pattern and a second insulating layer surrounding at least a portion of the pad structure, wherein
the pad structure includes a first pad layer on the first insulating layer and a second pad layer on the first pad layer, and
surfaces of the first pad layer in contact with the second insulating layer are concavo-convex and surfaces of the second pad layer in contact with the second insulating layer are concavo-convex.

2. The semiconductor package of claim 1, wherein
a horizontal length of the first pad layer in a first horizontal direction is greater than a horizontal length of the second pad layer in the first horizontal direction, and
the first horizontal direction is parallel to an upper surface of the first redistribution structure.

3. The semiconductor package of claim 1, further comprising:
a metal layer on the second pad layer, wherein
a portion of an upper surface of the second pad layer in contact with a lower surface of the metal layer is concavo-convex.

4. The semiconductor package of claim 3, wherein
a horizontal length of the second pad layer in a first horizontal direction is greater than a horizontal length of the metal layer in the first horizontal direction, and
the first horizontal direction is parallel to an upper surface of the first redistribution structure.

5. The semiconductor package of claim 3, wherein a material of the first pad layer and a material of the second pad layer are different from a material of the metal layer.

6. The semiconductor package of claim 1, wherein the first pad layer and the second pad layer comprise a same material.

7. The semiconductor package of claim 1, further comprising:
a metal layer on the second pad layer, wherein
a portion of an upper surface of the second pad layer in contact with a lower surface of the metal layer is a flat surface, and
the flat surface is not concavo-convex.

8. The semiconductor package of claim 1, wherein
the pad structure includes at least one of pad layers on the first pad layer,
the at least one of pad layers include a third pad layer on the second pad layer,
among surfaces of each of the at least one of pad layers, surfaces in contact with the second insulating layer are concavo-convex.

9. The semiconductor package of claim 8, wherein
horizontal lengths of the plurality of pad layers in a first horizontal direction decrease as distances of the plurality of pad layers from the semiconductor chip increase, and
the first horizontal direction is parallel to an upper surface of the first redistribution structure.

10. The semiconductor package of claim 1, wherein
the first redistribution pattern comprises a first redistribution line and a first redistribution via,
the first redistribution via extends from the first redistribution line in a vertical direction,
the vertical direction is perpendicular to an upper surface of the first redistribution structure,
the first redistribution via has a tapered shape in which a horizontal length thereof in a first horizontal direction decreases as a distance from the semiconductor chip increases, and
the first horizontal direction is parallel to the upper surface of the first redistribution structure.

11. The semiconductor package of claim 1, wherein
the first redistribution structure comprises a pad structure on a lower surface of the first redistribution insulating layer,
the pad structure is connected to the first redistribution pattern,
the pad structure comprises a metal layer on a lower surface of the first redistribution insulating layer, a first pad layer on the metal layer, and a second pad layer on the first pad layer, wherein
surfaces of the first pad layer in contact with the first redistribution insulating layer and surfaces of the second pad layer in contact with the first redistribution insulating layer are concave-convex.

12. The semiconductor package of claim 11, wherein
a horizontal length of the first pad layer in a first horizontal direction is greater than a horizontal length of the second pad layer in the first horizontal direction, and
the first horizontal direction is parallel to an upper surface of the first redistribution structure.

13. A semiconductor package comprising:
a first redistribution structure including a first redistribution pattern and a first redistribution insulating layer surrounding the first redistribution pattern;
a semiconductor chip on the first redistribution structure;
a second redistribution structure on the semiconductor chip, the second redistribution structure including a second redistribution pattern, a pad structure connected to the second redistribution pattern, and a second redistribution insulating layer including a first insulating layer surrounding the second redistribution pattern and a second insulating layer surrounding at least a portion of the pad structure;
an intermediate connection structure between the first redistribution structure and the second redistribution structure, the intermediate connection structure including an intermediate insulating layer and a plurality of through electrodes penetrating the intermediate insulating layer, the plurality of through electrodes electrically connecting the first redistribution structure to the second redistribution structure; and
a molding layer surrounding at least a portion of the semiconductor chip and at least a portion of the intermediate connection structure, wherein
the pad structure includes a first pad layer on a first insulating layer and a second pad layer on the first pad layer, and
surfaces of the first pad layer in contact with the second insulating layer are concavo-convex and surfaces of the second pad layer in contact with the second insulating layer are concavo-convex.

14. The semiconductor package of claim 13, wherein
the first redistribution pattern includes a first redistribution line and a first redistribution via,
the first redistribution via extends from the first redistribution line in a vertical direction,
the vertical direction is perpendicular to an upper surface of the first redistribution structure,
the first redistribution via has a tapered shape in which a length thereof in a first horizontal direction decreases as a distance from the semiconductor chip increases, and
the first horizontal direction is parallel to the upper surface of the first redistribution structure.

15. The semiconductor package of claim 13, wherein
a horizontal length of the first pad layer in a first horizontal direction is greater than a horizontal length of the second pad layer in the first horizontal direction, and
the first horizontal direction is parallel to an upper surface of the first redistribution structure.

16. The semiconductor package of claim 13, further comprising:
a metal layer on the second pad layer, wherein
a portion of an upper surface of the second pad layer in contact with a lower surface of the metal layer is concavo-convex.

17. The semiconductor package of claim 13, wherein
the pad structure includes at least one of pad layers on the first pad layer,
the at least one of pad layers include a third pad layer on the second pad layer, are concavo-convex.

18. A semiconductor package comprising:
a first redistribution structure including a first redistribution pattern and a first redistribution insulating layer surrounding the first redistribution pattern;
a semiconductor chip on the first redistribution structure;
a plurality of conductive posts spaced apart from the semiconductor chip, the plurality of conductive posts on the first redistribution structure;
a molding layer on the first redistribution structure, the molding layer surrounding the semiconductor chip and the plurality of conductive posts;
a second redistribution structure on the molding layer, the second redistribution structure including a second redistribution pattern, a pad structure connected to the second redistribution pattern, and a second redistribution insulating layer, the second redistribution insulating layer including a first insulating layer surrounding the second redistribution pattern and a second insulating layer surrounding at least a portion of the pad structure; and
an external connection terminal on a lower surface of the first redistribution structure, wherein
the pad structure comprises a first pad layer on a first insulating layer, a second pad layer on the first pad layer, a first metal layer on the second pad layer, and a second metal layer on the first metal layer,
surfaces of the first pad layer in contact with the second insulating layer are concavo-convex and surfaces of the second pad layer in contact with the second insulating layer are concavo-convex,
a horizontal length of the first pad layer in a first horizontal direction is greater than a horizontal length of the second pad layer in the first horizontal direction, and
the first horizontal direction is parallel to an upper surface of the first redistribution structure.

19. The semiconductor package of claim 18, wherein
the first pad layer and the second pad layer each comprise copper,
the first metal layer comprises nickel, and
the second metal layer comprises gold.

20. The semiconductor package of claim 19, wherein the first pad layer and the second pad layer each have a rectangular cross-sectional shape.
